(19) United States
(12) Patent Application Publication
(10) Pub. No.: US 2004/0007181 A1
(43) Pub. Date: Jan. 15, 2004

(54) Deposited-film formation process and formation system

(76) Inventor: Atsushi Yasuno, Nara (JP)

Correspondence Address: FITZPATRICK CELLA HARPER & SCINTO, 30 ROCKEFELLER PLAZA, NEW YORK, NY, 10112, US

(21) Appl. No.: 10/609,470

(22) Filed: Jul. 1, 2003

(30) Foreign Application Priority Data
Jul. 12, 2002 (JP) 204344/2002

(51) Int. Cl. C23C 16/00

(52) U.S. Cl. 118/723 E; 427/255.28

(57) ABSTRACT

A source gas is fed into a discharge space of a reactor and an electric power is applied to generate discharge in the discharge space to decompose the source gas, thereby forming a deposited film. A plurality of discharge means are disposed in the reactor. In the deposited-film formation, the following steps are switched from one to another at a given timing: i) a first step of applying an electric power to a first discharge means to generate discharge to form the deposited film and ii) a second step of applying an electric power to a second discharge means to generate discharge to form the deposited film.

### BACKGROUND OF THE INVENTION

1. Field of the Invention

This invention relates to a deposited-film formation process, and a formation system, in which source gases are decomposed by discharge to form deposited films.

2. Related Background Art

For photovoltaic devices used as solar cells and so forth, research and development have been focused on amorphous materials typified by amorphous silicon (a-Si:H) or non-single-crystal semiconductor materials such as microcrystalline silicon for the reasons that, e.g., they are inexpensive, can be made into large-area films and thin films, have a large freedom of composition, and enable electrical and optical properties to be controlled over a wide range. In the fabrication of such devices, deposited-film formation systems which form thin films by plasma-assisted CVD (chemical vapor deposition) under vacuum conditions are commonly in wide use and put into industrial use.

For the solar cells, it is fundamentally important to have sufficiently high photoelectric conversion efficiency, have good stability of characteristics and be able to be mass-produced. Accordingly, in the fabrication of solar cells making use of non-single-crystal semiconductor layers or the like, it is sought to make improvements in electrical, optical, photoconductive and mechanical properties, fatigue performance to repeated use and resistance to service environment of the solar cells to be fabricated, and also make it possible to mass-produce photovoltaic devices which have larger area and in which semiconductor layers of solar cells have more uniform layer thickness and film quality by forming films at high speed in reproducible manners.

In the solar cells, the semiconductor layers, which serve as an important component of the solar cells, are formed to have semiconductor junctions such as p-n junction and p-i-n junction. Where a semiconductor of a-Si or the like in thin film form is used, source gases, for example, silane (SiH₄) and phosphine (PH₃) or diborane (B₂H₆) containing an element coming to a dopant, are mixed and glow discharge is effected to decompose the source gases, where the resulting elements are deposited onto the surface of a heated solid (plasma-assisted CVD), whereby a semiconductor layer of a desired conductivity type can be obtained. It is known that in such a way, semiconductor layers of desired conductivity types are superposed one on another on a desired substrate and thereby these semiconductor layers can be easily made to have semiconductor junctions. Thus, as a fabrication method for solar cells obtained by superposing non-single-crystal semiconductor layers, a method is proposed in which independent semiconductor layer forming reactors for forming the respective semiconductor layers are provided and the respective semiconductor layers are formed in order in the semiconductor layer forming reactors to produce a stack of semiconductor layers formed to have the desired semiconductor junctions.

For example, U.S. Pat. No. 4,400,409 discloses a continuous plasma-assisted CVD system employing a roll-to-roll method. This system is a system in which, in a transport path provided with a plurality of glow discharge regions for forming semiconductor layers by effecting glow discharge, a flexible substrate having a desired width and a sufficient length is continuously transported therethrough so that semiconductor layers of required conductivity types are successively deposited on the substrate in the respective glow discharge regions to continuously fabricate a device having a plurality of semiconductor layers formed to have semiconductor junctions.

Japanese Patent Application Laid-Open Nos. 06-184755 and 07-235504 disclose a method in which, in such a continuous plasma-assisted CVD system, the substrate is heated in the vicinities of the inlets of the glow discharge regions and cooled in the vicinities of the outlets of the glow discharge regions.

However, with the above photovoltaic device mass production systems a problem arises in that the inner-wall temperature and electrode temperature in reactors may inevitably rise over time to cause changes in the balance of heat in the reaction system between the initial stage and the latter stage of film formation. Stated specifically, it becomes difficult to control the substrate temperature within the temperature range that enables good-quality semiconductor layers to be deposited, and such changes may deteriorate the film quality of p-type semiconductor layers or damage underlying i-type semiconductor layers to cause a great lowering of productivity. In particular, the rise of temperature at the time of forming p-type semiconductor layers causes a lowering of solar-cell characteristics Voc (open-circuit voltage), and is greatly concerned in a lowering of photoelectric conversion efficiency.

Much higher power must also be applied when the substrate-processing speed is made higher at the time of mass production, and hence such temperature rise may also come to occur more remarkably.

In addition, for the purpose of more improving film formation speed, improving characteristics or improving film quality uniformity, the distance between a discharge means and its opposing-electrode substrate is made smaller (e.g., 5 to 50 mm, and particularly 20 mm or less) and the pressure inside the reactor is made higher (e.g., 10 to 800 Pa, and particularly 200 Pa or more). This brings ab out an abrupt increase in the amount of heat flowing into the discharge space. Hence, the above problem of temperature rise comes more remarkable, and at the same time it becomes more difficult to control temperature.

It is conventionally known to spray cooling gas on the back of the substrate or provide a cooling member in order to keep the substrate from undergoing temperature rise. However, this may make the heat flow in a poor efficiency especially in vacuum systems, and may make substantial temperature control difficult when the amount of heat flowing to the substrate under the above conditions for film formation becomes larger than the amount of heat that can be made smaller by cooling.

Thus, in conventional cases, the substrate can not be controlled to the desired temperature when high-temperature heat treatment of the substrate or film formation processing under the application of high power is performed, and it has been unavoidable that characteristics lowers gradually with time. More specifically, there has been such a problem that in the fabrication of semiconductor devices over a long time at the time of mass production, the scattering of the characteristics of semiconductor devices over time has occurred. Such a problem more or less lies in the formation of deposited films in general, without being limited to the case in which semiconductor devices such as photovoltaic devices are fabricated.

### SUMMARY OF THE INVENTION

An object of the present invention is to provide a deposited-film formation process and a formation system having high productivity, which can prevent characteristics from lowering with time in the long-time film formation with the deposited film formation system as described above and can keep minimum the scattering of characteristics at the time of mass production, to stably fabricate photovoltaic devices having high photoelectric conversion efficiency.

To achieve the above object, the deposited-film formation process of the present invention is a deposited-film formation process in which a source gas is fed into a discharge space of a reactor and an electric power is applied to generate discharge in the discharge space to decompose the source gas, thereby forming a deposited film; the process being characterized by disposing a plurality of discharge means in the reactor and having:

a first step of applying an electric power to a first discharge means to generate discharge to form the deposited film; and

a second step of applying an electric power to a second discharge means to generate discharge to form the deposited film;

the first step and the second step being switched from one to another at a stated timing.

In another embodiment of the present invention, the process is characterized by having:

a first step of applying to the first discharge means an electric power larger than that for the second discharge means to generate discharge to form the deposited film; and

a second step of applying to the second discharge means an electric power larger than that for the first discharge means to generate discharge to form the deposited film;

the first step and the second step being switched from one to another at a stated timing. In this process, it is preferable that in the first step the electric power is applied to the second discharge means to generate discharge to an extent that does not affect the film formation, and in the second step the electric power is applied to the first discharge means to generate discharge to an extent that does not affect the film formation.

The deposited-film formation system of the present invention is a deposited-film formation system in which a source gas is fed into a discharge space of a reactor and an electric power is applied to generate discharge in the discharge space to decompose the source gas, thereby forming a deposited film; the system being characterized by having:

a plurality of discharge means disposed in the reactor; and

a means for switching i) a first step of generating discharge by a first discharge means to form the deposited film and ii) a second step of generating discharge by a second discharge means to form the deposited film, from one to another on the basis of a value detected by a means for detecting a stated film formation parameter.

In the deposited-film formation process and system, a plurality of reactors having at least one discharge means may be provided.

The deposited-film formation process and system are further characterized in that the first step and the second step are switched from one to another on the basis of the film formation temperature that has reached a temperature within a temperature range set beforehand. The switching may also be performed on the basis of the self-bias voltage that has reached to a voltage within a voltage range set beforehand. The switching may still also be performed on the basis of the self-bias electric current that has reached an electric current within an electric-current range set beforehand. The switching may further be performed within a film formation time range set beforehand.

It is also preferable that the first and second discharge means are kept controlled within a stated temperature range and, when the first step and the second step are switched from one to another, the electric power for the first discharge means is gradually decreased or increased and the electric power for the second discharge means is gradually increased or decreased.

The deposited-film formation process and system are still further characterized in that the deposited films formed through the first and second discharge means are semiconductor layers having the same conductivity type, and the distance between the first and second discharge means and the substrate on which the deposited films are formed is in the range of from 5 mm to 50 mm, and the pressure at which the deposited films are formed is in the range of from 10 Pa to 800 Pa.

### BRIEF DESCRIPTION OF THE DRAWINGS

FIG. 1 is a schematic view showing a deposited-film formation system according to an embodiment of the present invention.

FIG. 2 is a schematic view showing a deposited-film formation system according to a comparative embodiment.

FIG. 3 is a diagrammatic illustration of the construction of a p-i-n type non-single-crystal solar cell fabricated by means of the deposited-film formation system of the present invention.

FIG. 4 is a schematic view showing an example of the deposited-film formation system of the present invention.

FIG. 5 is a schematic view showing another example of the deposited-film formation system of the present invention.

FIG. 6 is a graph in which the initial photoelectric conversion efficiency η of photovoltaic devices is plotted in an Example of the present invention; the devices being obtained when the step of switching discharge is carried out, and being sampled at certain constant intervals of the film formation time.

FIG. 7 is a graph in which the initial photoelectric conversion efficiency η of photovoltaic devices is plotted in a Comparative Example for the present invention; the devices being obtained when the step of switching discharge is not carried out, and being sampled at certain constant intervals of the film formation time.

### DESCRIPTION OF THE PREFERRED EMBODIMENTS

The present invention is described below in detail with reference to the accompanying drawings. The deposited-film formation process and formation system of the present invention are by no means limited to the following embodiments.

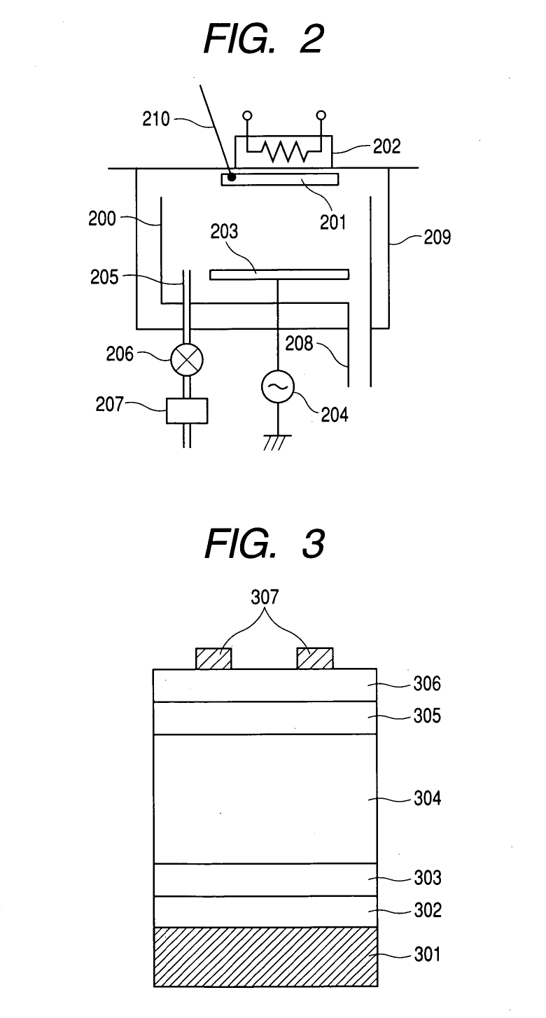

FIG. 2 is a schematic view showing a conventional semiconductor layer formation system diagrammatically.

As shown in FIG. 2, a reactor inner container 200 which defines a discharge space is set in the interior of a reactor outer container 209. A substrate 201 is so set as to come into close contact with a heater 202 set on the reactor outer container 209. The reactor inside is evacuated through an exhaust tube 208 by means of an exhaust system (not shown). Thereafter, the substrate 201 is heated to a desired temperature. Substrate temperature is measured with a thermocouple 210 and controlled at the desired temperature by a temperature control system (not shown). At the time the substrate temperature has come stable, a gas feed valve 206 is opened, and, controlling the flow rate by means of a mass flow controller 207, a source gas containing silicon atoms is fed into the reactor inner container 200 (discharge space) through a gas feed pipe 205.

Next, a high-frequency power is applied to a cathode electrode 203 from a high-frequency power source 204 to generate discharge. Here, the reactor wall and the substrate are both earthed, and the discharge spreads uniformly in the reactor. The substrate temperature is kept controlled when the discharge is started, but the environmental temperature inclusive of the electrode temperature, inner-wall temperature and so forth in the reactor inner container 200 rises on and on with time. Especially in the case of a mass-production system, substrates to be processed are continuously introduced into the reactor and films are formed over a long time, and hence, as for substrates processed in the latter half, films are formed in the state the environmental temperature is considerably high. Hence, it becomes difficult to control the substrate temperature stably, so that a lowering of characteristics has been seen.

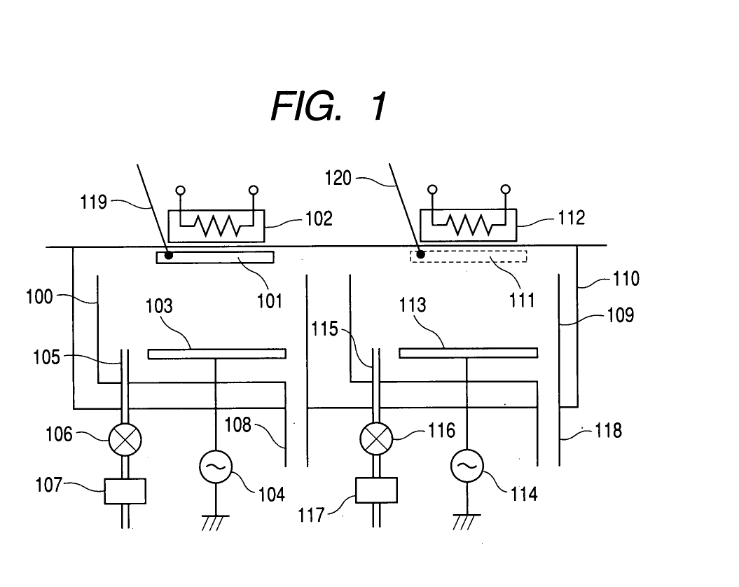

FIG. 1 is a schematic view diagrammatically showing a semiconductor layer formation system which is used to carry out the deposited-film formation process of the present invention.

As shown in FIG. 1, a reactor first inner container 100 and a reactor second inner container 109 which each define a discharge space are set in the interior of a reactor outer container 110. A substrate 101 is so set as to come into close contact with a heater 102 set on the reactor outer container 110. The reactor inside is evacuated through an exhaust tube 108 by means of an exhaust system (not shown), and thereafter the substrate 101 is heated to a desired temperature. Substrate temperature is measured with a thermocouple 119 and controlled at the desired temperature by a temperature control system (not shown). At the time the substrate temperature has come stable, a gas feed valve 106 is opened, and, controlling the flow rate by means of a mass flow controller 107, a source gas containing silicon atoms is fed into the reactor first inner container 100 (discharge space) through a gas feed pipe 105.

Next, a high-frequency power is applied to a cathode electrode 103 from a high-frequency power source 104 to generate discharge. Here, as with the conventional system shown in FIG. 2, the film formation temperature in the reactor first inner container 100 rises on and on with time as the number of films formed on substrates increases.

Here, the film formation temperature in the present invention refers to environmental temperature including at least one of substrate temperature, electrode temperature and inner-wall temperature, or average temperature of these.

With a rise of this film formation temperature, it becomes difficult to make control to the desired substrate temperature to cause a lowering of characteristics of the films formed.

With an increase in the number of films formed, it becomes difficult to control the substrate temperature and the value indicated by the thermocouple 119 comes larger than the desired temperature, at the time that a substrate 111 to be processed next is so set as to come into close contact with another heater 112 provided in the same reactor outer container 110 and the discharge means (first discharge means) is switched to the discharge means (second discharge means) having the other unused reactor second inner container 109 and a cathode electrode 113 to continue the film formation.

Here, as to the timing at which the discharge means (cathode electrodes) are switched from one to another, the switching may preferably be carried out on the basis of, e.g., film formation temperature. Stated specifically, a means for detecting the film formation temperature is provided so that the discharge means can be switched when the value detected has reached to a temperature within a temperature range set beforehand (e.g., above a preset temperature).

As to the order of the switching of discharge in this embodiment, first the reactor inside is evacuated through an exhaust tube 118 by means of an exhaust system (not shown), and thereafter the substrate 111 is heated to a desired temperature. Substrate temperature is measured with a thermocouple 120 and controlled at the desired temperature by a temperature control system (not shown). At the time the substrate temperature has come stable, a gas feed valve 116 is opened, and, controlling the flow rate by means of a mass flow controller 117, a source gas containing silicon atoms is fed into the reactor second inner container 109 (discharge space) through a gas feed pipe 115.

Next, a high-frequency power is applied to a cathode electrode 113 from a high-frequency power source 114 to generate discharge. Here, the environmental temperature in the reactor second inner container 109 is sufficiently low, and hence the substrate temperature is kept controlled at the desired temperature, where semiconductor layers having good characteristics can be obtained.

In the system in which films are continuously formed, the discharge of the first and second discharge means may simultaneously be made ON/OFF when the discharge means is switched as described above. However, depending on the timing at the instant of switching, the characteristics of films formed may lower. Besides, when the discharge is generated by the discharge means which has been stopped, it may take a certain time until the discharge comes stable. Accordingly, the processing may preferably be carried out in the following way.

1. Timing at which the first and second discharge means generate discharge simultaneously is provided. For example, the time during which they generate discharge simultaneously for 1 to 20 seconds may be provided. However, if this time is too short, the stability of discharge may lower, and, if too long, the characteristics may be lowered.

2. Electric power which is substantially weak enough not to affect film formation is applied to the second discharge means to make weak discharge to take place beforehand, and the first discharge means and the second discharge means may gradually be switched from one to another.

The timing at which the first discharge means and the second discharge means are switched from one to another may preferably be set, e.g., in the following way.

In the first place, the relationship between the film formation temperature and characteristics is beforehand determined to previously grasp an optimum temperature range for attaining the desired characteristics. Next, the temperature is detected during the film formation and the discharge means is switched so as to maintain the optimum temperature range. Here, if it is difficult to detect temperature at the time of actual film formation, the relationship between the temperature rise and time may beforehand be determined so that the time of switching can previously be set.

As other ways of setting the timing of switching, available are those set on the basis of changes in self-bias voltage, changes in self-bias electric current and the like at the time of plasma discharge. Stated specifically, a means for detecting self-bias voltage or self-bias electric current may be provided, where the discharge means is switched when either or both of the values detected on these has or have reached a preset voltage or electric current range. That is, an optimum range for attaining the desired characteristics is beforehand grasped, and the discharge means is switched so as to maintain the optimum range.

In the present invention, the discharge means may also be provided in a further large number as needed (e.g., 10 means), and these may be switched from one to another in order, or one set of a plurality of means may be switched from one to another alternately.

The switching of discharge means as described above makes it possible to prevent characteristics from lowering with time because of the substrate temperature rise due to long-time film formation in the deposited-film formation systems and to keep minimum the scattering of characteristics at the time of mass production.

FIG. 3 is a diagrammatic illustration of the construction of a p-i-n type non-single-crystal solar cell which can be fabricated by the deposited-film formation process and formation system of the present invention. FIGS. 3 shows a solar cell having structure in which light enters the inside from the top as viewed in the drawing. In FIG. 3, reference numeral 301 denotes a substrate; 302, a lower electrode; 303, an n-type semiconductor layer; 304, an i-type semiconductor layer; 305, a p-type semiconductor layer; 306, an upper electrode; and 307, a collector electrode.

(Substrate)

As suitable substrates 301 on which semiconductor layers are to be deposited, single-crystal ones or non-single-crystal ones may be used, and they may be conductive ones or insulating ones. They may still also be light-transmitting ones or non-light-transmitting ones, but may preferably be those having less deformation or strain and having the desired strength.

They may specifically be thin sheets of metals such as Fe, Ni, Cu, Zn, Cr, Al, Mo, Au, Nb, Ta, V, Ti, Pt and Pb, or alloy of any of these as exemplified by brass and stainless steel, and composites of such sheets; films or sheets of heat-resistant synthetic resins such as polyester, polyethylene, polycarbonate, cellulose acetate, polypropylene, polyvinyl chloride, polyvinylidene chloride, polystyrene, polyamide, polyimide and epoxy, or composites of any of these with glass fiber, carbon fiber, boron fiber, metal fiber or the like; resin sheets surface-coated by sputtering, vacuum deposition, plating or the like to have on their surfaces metal thin-films of different materials and/or insulating films of SiO₂, Si₃N₄, Al₂O₃, AlN or the like; and sheets of glass, ceramics and so forth.

Where the substrate is an electrically conductive material such as a metal, it may be used as an electrode for taking out electric current directly therethrough. Where it is an electrically insulating material such as a synthetic resin, an electrode for taking out electric current directly therethrough may preferably beforehand be formed on the surface on the side where the deposited films are to be formed, by previously conducting surface treatment by plating, vacuum deposition, sputtering or the like of a metal alone or an alloy, such as Al, Ag, Pt, Au, Ni, Ti, Mo, W, Fe, V, Cr, Cu, stainless steel, brass, nichrome, SnO₂, In₂O₃, ZnO or ITO (indium-tin oxide), or a transparent conductive oxide (TCO). Of course, even where the substrate is an electrically conductive material such as a metal, a different kind of metal layer may be provided on the substrate on its side where the deposited films are to be formed, in order to, e.g., improve the reflectance of long-wave light on the substrate surface or prevent constituent elements from diffusing mutually across substrate materials and deposited films.

As for the surface properties of the substrate, it may have a flat surface or a microscopically uneven surface. In the case where the substrate is made to have a microscopically uneven surface, the unevenness may, e.g., be spherical, conical or pyramidal in shape, and may preferably have a maximum height (Rmax) of from 50 nm to 500 nm. This allows the substrate surface to irregularly reflect light, and increases the light path length of the reflected light on the surface. The thickness of the substrate may appropriately be determined so that photovoltaic devices as desired can be formed. In view of the fabrication, handling, mechanical strength and so forth of substrates, the substrate may usually have a thickness of 10 μm or more.

In the photovoltaic device obtained by the process and system of the present invention, appropriate electrodes are selected according to the structural form of the device. Such electrodes may include a lower electrode, an upper electrode (transparent electrode) and a collector electrode. It should be noted that the upper electrode herein referred to indicates one provided on the light-incident side and that the lower electrode indicates one provided on the side opposite to the upper electrode interposing the semiconductor layers between them. These electrodes and also semiconductor layers are described below in detail.

(Lower Electrode)

The lower electrode 302 is provided between the substrate 301 and the n-type semiconductor layer 303. However, where the substrate 301 is conductive, the substrate may serve also as the lower electrode. However, even where the substrate 301 is conductive, it may have a high sheet resistivity. In such a case, the electrode 302 may be provided as a low-resistance electrode for taking out electric current or for the purpose of improving the reflectance on the substrate surface so as to effectively utilize the light having entered the inside.

Materials for the lower electrode may include metals such as Ag, Au, Pt, Ni, Cr, Cu, Al, Ti, Zn, Mo and W, and alloys of any of these. A thin film of any of these metals (inclusive of alloys) is formed by vacuum deposition, electron beam deposition, sputtering or the like. Care must be taken that the metal thin film thus formed does not become any resistance components against the output from the photovoltaic device.

While not shown in the drawing, a diffusion preventive layer formed of conductive zinc oxide or the like may be provided between the lower electrode 302 and the n-type semiconductor layer 303. As for the effects attributed to the diffusion preventive layer, this layer not only can prevent metallic elements which constitute the lower electrode 302, from diffusing into the n-type semiconductor layer 303, but also, when made to have a little resistivity, can prevent any defects such as pinholes from causing a short circuit across the lower electrode 302 and the upper electrode 306 which are provided interposing semiconductor layers between them, and also can induce multiple interference attributable to the thin film to confine in the photovoltaic device the light having entered it.

(Upper Electrode, Transparent Electrode)

As the transparent electrode (upper electrode) 306, it may preferably have a light transmittance of 85% or more in order that the light from the sun, white luminescent lamps and the like can be absorbed in the semiconductor layers in a good efficiency. It may further preferably have a sheet resistivity of 300 Ω/square or less so that it electrically does not come to any resistance component against the output from the photovoltaic device. Materials having such characteristics may include, e.g., metal oxides such as SnO₂, In₂O₃, ZnO, CdO, CdSnO₄, ITO (In₂O₃+SnO₂) and metal thin films obtained by forming metals such as Au, Al and Cu in a very thin and semitransparent state.

The transparent electrode 306 is, as shown in FIG. 3, superposed on the p-type semiconductor layer 305, and hence one having good adhesion to the layer 305 may preferably be selected. As processes for forming such an electrode, resistance heating evaporation, electron beam evaporation, sputtering, spraying and so forth may be used, and any of them may appropriately be selected as desired.

(Collector Electrode)

The collector electrode 307 is provided on the transparent electrode 306 for the purpose of reducing the surface resistivity of the transparent electrode 306. Electrode materials may include thin films of metals such as Ag, Cr, Ni, Al, Ag, Au, Ti, Pt, Cu, Mo and W, or alloys of any of these. Such thin films may be used in a superposed state. Its shape and area may also appropriately be designed so that the amount of light having entered the semiconductor layers can sufficiently be ensured.

For example, the electrode 307 may preferably have such a shape that it extends uniformly with respect to the light-receiving surface of the photovoltaic device and is in an area of 15% or less, and more preferably 10% or less, of that light-receiving surface. It may also preferably have a sheet resistivity of 50 Ω/square or less, and more preferably 10 Ω/square or less.

(Semiconductor Layers)

The semiconductor layers 303, 304 and 305 may be formed by using known processes such as vacuum evaporation, sputtering, high-frequency plasma-assisted CVD, microwave plasma-assisted CVD, ECR (electron cyclotron resonance) plasma-assisted CVD, thermal CVD and LPCVD (low-pressure CVD). As a process employed in an industrial scale, the plasma-assisted CVD may preferably be used, in which source gases are decomposed by plasma to deposit films on substrates.

As reaction systems, batch type systems or continuous film formation systems may be used as desired. Where valence-electron-controlled semiconductors are fabricated, a gas containing phosphorus, boron and so forth as constituent atoms, such as PH₃ or B₂H₆, is simultaneously decomposed.

(i-Type Semiconductor Layer)

Semiconductor materials constituting the i-type semiconductor layer which are preferably usable in the photovoltaic device may include, when an i-type semiconductor layer of amorphous silicon germanium is used, Group IV element alloy type semiconductor materials such as a-SiGe:H, a-SiGe:F and a-SiGe:H:F. Also, as semiconductor materials constituting the i-type semiconductor layer other than that of amorphous silicon germanium in a tandem cell structure in which unit device components are stacked, they may include Group IV element or Group IV element alloy type semiconductor materials such as a-Si:H, a-Si:F, a-Si:H:F, a-SiC:H, a-SiC:F, a-SiC:H:F, poly-Si:H, poly-Si:F and poly-Si:H:F, as well as Groups III-V element and Groups III-VI element compound semiconductor materials.

As source gases used in CVD, chainlike or cyclic silane compounds are used as compounds containing a silicon element, specifically including, e.g., gasified or readily gasifiable compounds such as SiH₄ SiF₄, (SiF₂)₅, (SiF₂)₆, (SiF₂)₄, Si₂F₆, Si₃F₈,SiHF₃, SiH₂F₂, Si₂H₂F₄, Si₂H₃F₃, SiCl₄, (SiCl₂)₅, SiBr₄, (SiBr₂)₅, SiCl₆, SiHCl₃, SiHBr₂, SiH₂Cl₂ and SiCl₃F₃.

As compounds containing a germanium element, they may include chainlike germanes or germanium halides, cyclic germanes or germanium halides, chainlike or cyclic germanium compounds, and organogermanium compounds having an alkyl group, stated specifically, GeG₄, Ge₂H₆, Ge₃H₈, n-Ge₄H₁₀, t-Ge₄, H₁₀, Ge₅H₁₀, GeH₃Cl, GeH₂F₂, Ge(CH₃)₄, Ge(C₂H₅)₄, Ge(C₆H₅)₄, Ge(CH₃)₂F₂, GeF₂ and GeF₄.

(p-Type and n-Type Semiconductor Layers)

Semiconductor materials constituting the p-type or n-type semiconductor layer which are preferably usable in the photovoltaic device are obtained by doping the above materials constituting the i-type semiconductor layer, with a valence electron control agent. As materials, when deposited films of Group IV elements of the periodic table are obtained, compounds containing Group III elements of the periodic table are used as a valence electron control agent for obtaining the p-type semiconductor layer. The Group III element may include boron (B), and compounds containing B may specifically include BF₃, B₂H₆, B₄H₁₀, B₅H₉, B₅H₁₁, B₆H₁₀, B(CH₃)₃, B(C₂H₅)₃ and B₆H₁₂.

As a valence electron control agent for obtaining the p-type semiconductor layer, compounds containing Group V elements of the periodic table are used. The Group V element may include phosphorus (P) and nitrogen (N), and compounds containing any of these may specifically include N₂, NH₃, N₂H₅N₃, N₂H₄, NH₄N₃, PH₃, P(OCH₃)₃, P(OC₂H₅)₃, P(C₃H₇)₃, P(OC₄H₉)₃, P(CH₃)₃, P(C₂H₅)₃, P(C₃H₇)₃, P(C₄H₉)₃, P(OCH₃)₃, P(OC₂H₅)₃, P(OC₃H₇)₃, P(OC₄H₉)₃, P(SCN)₃, P₂H₄ and PH₃.

### EXAMPLES

Examples of the deposited-film formation process and formation system of the present invention are given below. The present invention is by no means limited to the following Examples.

### Example 1

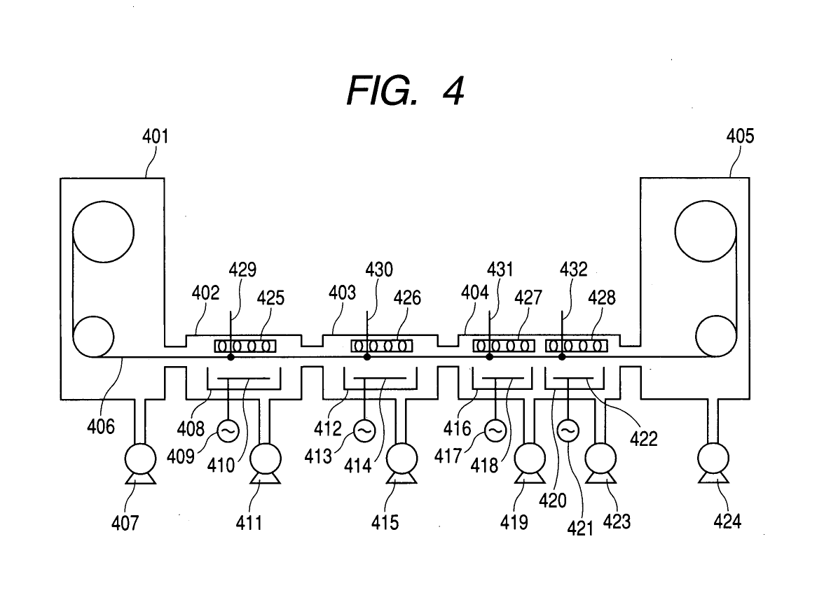

A process of continuously fabricating the FIG. 3 photovoltaic device by the use of a system shown in FIG. 4 is described below.

FIG. 4 is a diagrammatic view illustrating a deposited-film formation system for continuously fabricating the photovoltaic device. This system is basically constituted of a beltlike substrate 406, a delivery chamber 401, a wind-up chamber 405, an n-type semiconductor layer forming reactor 402, an i-type semiconductor layer forming reactor 403 and a p-type semiconductor layer forming reactor 404 which are connected via gas gates. Reference numerals 407, 411, 415, 419, 423 and 424 denote vacuum pumps, and reference numerals 410, 414, 418 and 422 denote cathode electrodes which are connected to RF power sources 409, 413, 417 and 421, respectively.

In the respective reactors 402, 403 and 404, reactor inner containers 408, 412, 416 and 420, respectively, are provided. In particular, in the p-type semiconductor layer forming reactor 404, two reactor inner containers 416 and 420 are provided.

In the respective reactors, infrared lamp heaters 425, 426, 427 and 428 are also provided at spaces on the side opposite to the film formation space, interposing the beltlike substrate 406 between them. Thermocouples 429, 430, 431 and 432 for monitoring the temperature of the beltlike substrate 406 are respectively so connected as to come into contact with the beltlike substrate 406, and the substrate is controlled to the desired temperature by means of a temperature control system (not shown).

First, in the delivery chamber 401 of this deposited-film formation system, having a substrate delivery mechanism, a bobbin was set which was wound up with a beltlike substrate 406 (300 mm wide×0.2 mm thick) made of SUS 430BA stainless steel, having been sufficiently degreased and cleaned and on which a thin silver film 100 nm thick and a thin ZnO film 1 μm thick were vacuum-deposited as the lower electrode by sputtering. Then the beltlike substrate 406 was allowed to pass through the n-type semiconductor layer forming reactor 402, the i-type semiconductor layer forming reactor 403, the p-type semiconductor layer forming reactor 404 and up to the wind-up chamber 405, having a substrate wind-up mechanism, and its tension was adjusted to an extent that it did not slacken. Here, the distance between the substrate and the cathode electrodes is so set as to be 20 mm.

Next, the insides of the delivery chamber 401, reactors 402, 403 and 404 and wind-up chamber 405 were evacuated to a vacuum of 1×10⁻⁴ Pa or less by means of the vacuum pumps 407, 411, 415, 419, 423 and 424, respectively. As heat treatment before the film formation, 500 sccm each of He gas was fed into the reactors 402, 403 and 404 through gas feed pipes (not shown). The valve travel of throttle valves was so adjusted that the internal pressure of each of the delivery chamber 401, reactors 402, 403 and 404 and wind-up chamber 405 came to be 130 Pa, where the insides of the respective chambers and reactors were evacuated by means of the vacuum pumps. The sccm (standard cubic centimeter per minute) used here is a unit of flow rate, and 1 sccm is 1 cm³/min (standard state). Hereinafter, the unit of flow rate is represented by sccm. Thereafter, the beltlike substrate 406 and the inside materials of the reactors 402 to 404 were heated to 400° C. by means of the infrared lamp heaters 425, 426, 427 and 428 for heating. In this state, the system was left standing for 1 hour.

Next, in preparation for n-type semiconductor layer film formation, a temperature control device (not shown) was so set that the value of temperature indicated by the thermocouple 429 came to be 270° C., and the beltlike substrate 406 was heated with the infrared lamp heater 425. Through gas feed inlets (not shown), 100 sccm of SiH₄ gas, 500 sccm of PH₃/H₂(1%) gas and 700 sccm of H₂ gas were fed into the reactor inner container 408. The valve travel of a conductance control valve was so adjusted that the pressure of the discharge chamber came to be 130 Pa, followed by evacuation by means of the vacuum pump 411. The discharge means was so set that the output value of the RF (13.56 MHz) power source 409 came to be 100 W, and the RF power was applied to the electrode 410 to generate discharge in the reactor inner container 408.

In preparation for i-type semiconductor layer film formation, a temperature control device (not shown) was so set that the value of temperature indicated by the thermocouple 430 came to be 300° C., and the beltlike substrate 406 was heated with the infrared lamp heater 426. Through the gas feed inlet (not shown), 800 sccm of SiH₄ gas, 900 sccm of GeH₄ gas and 3000 sccm of H₂ gas were fed into the reactor inner container 412. The valve travel of a conductance control valve was so adjusted that the pressure of the discharge chamber came to be 130 Pa, followed by evacuation by means of the vacuum pump 415. The discharge means was so set that the output value of the RF (13.56 MHz) power source 413 came to be 1,500 W, and the RF power was applied to the electrode 414 to generate discharge in the reactor inner container 412.

In preparation for p-type semiconductor layer film formation, temperature control devices (not shown) were so set that the values of temperature indicated by the thermocouples 431 and 432 came to be 150° C., and the beltlike substrate 406 was heated with the infrared lamp heaters 427 and 428. Through the gas feed inlets (not shown), 10 sccm of SiH₄ gas, 500 sccm of BF₃/H₂ (1%) gas and 5,000 sccm of H₂ gas were fed into each of the reactor inner containers 416 and 420 each. The valve travel of a conductance control valve was so adjusted that the pressure of the discharge chamber came to be 130 Pa, followed by evacuation by means of the vacuum pumps 419 and 423. The discharge means was so set that the output value of the RF power source 417 came to be 2,000 W, and the RF power was applied to the electrode 418 to generate discharge in the reactor inner container 416. Discharge was not yet generated in the reactor inner container 420.

Subsequently after the preparation for the film formation of the respective layers, the beltlike substrate 406 was transported at a speed of 1,000 mm/min to start the formation of the n-type semiconductor layer, i-type semiconductor layer and p-type semiconductor layer on the beltlike substrate 406.

About 2.5 hours after the starting of the film formation, the value indicated by the thermocouple 431 above the reactor inner container 416 for the p-type semiconductor layer film formation came larger than the preset value 150° C., and at this time point, the discharge means was so set that the output value of the RF power source 421 came to be 2,000 W, and the RF power was applied to the electrode 422 to generate discharge in the reactor inner container 420. After the discharge took place in the reactor inner container 420, the electric power from the RF power source 417 was stopped to extinguish the discharge in the reactor inner container 416 (first discharge switching step).

After this first discharge switching step, the thermocouple 432 indicated 150° C., and the film formation was continued in a temperature-controlled state, where the value indicated by the thermocouple 431 that had exceeded 150° C. returned to the state it was controlled at 150° C.

Thereafter, the film formation was continued, and the value indicated by the thermocouple 432 above the reactor inner container 420 came larger than the preset value 150° C., and at this time point, the discharge means was so set that the output value of the RF power source 417 came to be 2,000 W, and the RF power was applied to the electrode 418 to generate discharge in the reactor inner container 416. After this discharge took place, the electric power from the RF power source 421 was stopped to extinguish the discharge in the reactor inner container 420 (second discharge switching step).

Also in the subsequent film formation, the above series of first and second discharge switching steps were repeated at the point of time when the value of temperature indicated by the thermocouple in the p-type semiconductor layer film formation reactor in which discharge was kept generated came larger than the preset value 150° C., continuing the film formation.

After the beltlike substrate 406 was transported for one roll, all the discharge, all the gas feed, all the electrification of lamp heaters and the transport of the beltlike substrate 406 were stopped. Next, chamber purging N₂ gas was fed into chambers (feeding member not shown) to return the inside to the atmospheric pressure, and the beltlike substrate having the respective semiconductor layers formed thereon and wound up in the wind-up chamber 405 was taken out.

The beltlike substrate having the respective semiconductor layers formed thereon, thus taken out, was cut into unit cells. On the p-type semiconductor layer of each unit cell, ITO (In₂O₃+SnO₂) was deposited by vacuum deposition in a thickness of 100 nm as the transparent electrode, and further Al was deposited by vacuum deposition in a thickness of 1 μm as the collector electrode. Thus, photovoltaic devices were fabricated.

As a comparative example of Example 1 (Comparative Example 1), photovoltaic devices were fabricated in the same manner as in Example 1 except that the first and second discharge switching steps were not carried out in the p-type semiconductor layer film formation, the RF power source 417 and the electrode 418 were used from the beginning of film formation until the completion of film formation for one roll of the beltlike substrate 406 and the discharge was generated only in the reactor inner container 416 without being generated in the reactor inner container 420.

To make evaluation, samples of Example 1 and Comparative Example 1 were irradiated with the light of a sunlight spectrum of AM −1.5 at an intensity of 100 mW/cm², using a solar simulator, and a voltage-current curve was prepared to measure the initial photoelectric conversion efficiency of the photovoltaic devices.

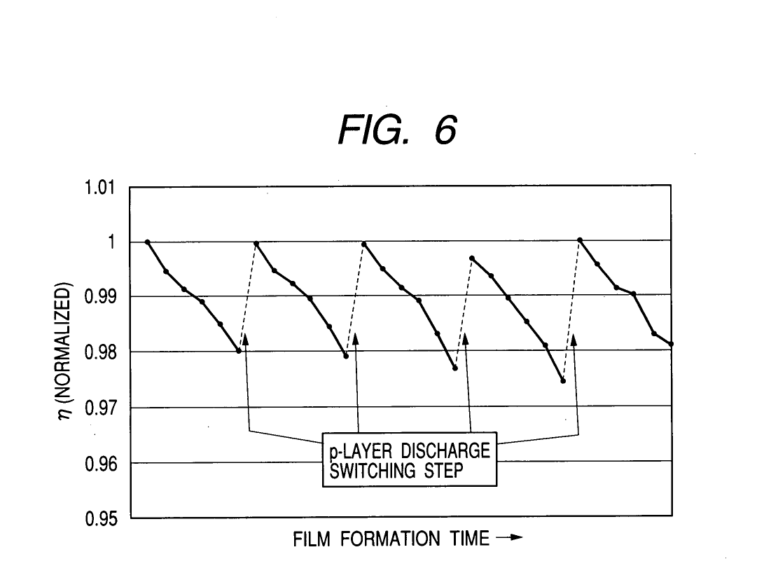

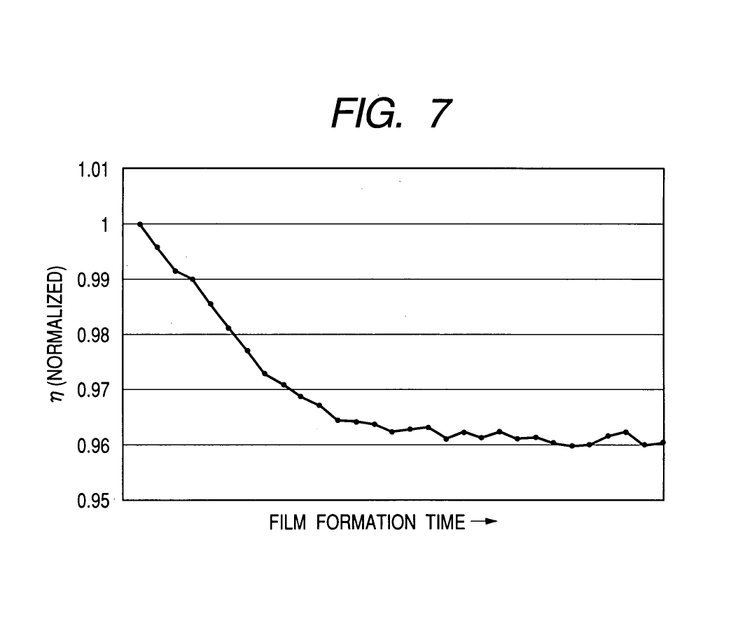

FIG. 6 is a graph in which the initial photoelectric conversion efficiency η of photovoltaic devices is plotted; the devices being obtained in Example 1 and sampled at certain constant intervals of film formation time. The initial photoelectric conversion efficiency η (normalized) is plotted as ordinate, and the film formation time as abscissa. Here, the initial photoelectric conversion efficiency η (normalized) is represented by standardizing as 1 the conversion efficiency at the time the film formation is started. FIG. 7 is also a graph in which the initial photoelectric conversion efficiency of photovoltaic devices obtained in Comparative Example 1 is plotted.

It was ascertained that in the photovoltaic devices fabricated in Comparative Example 1, the initial photoelectric conversion efficiency showed a tendency to decrease with the passage of film formation time, but, in the photovoltaic devices fabricated in Example 1, the initial photoelectric conversion efficiency was restored every time the discharge switching step was carried out in the p-type semiconductor layer film formation, and it was also confirmed that the Voc (open-circuit voltage) was similarly restored.

### Example 2

In this Example, photovoltaic devices were fabricated in the same manner as in Example 1 except that the p-type semiconductor layer was formed under the following conditions for film formation.

In this Example, in preparation for p-type semiconductor layer film formation, the discharge means was so set that the output value of the RF power source 417 came to be 2,000 W, and the RF power was applied to the electrode 418 to generate discharge in the reactor inner container 416. At the same time, the discharge means was so set that the output value of the RF power source 421 came to be 200 W, and the RF power was applied to the electrode 422 to generate discharge in the reactor inner container 420. About 2.5 hours after the beginning of the film formation, the value indicated by the thermocouple 431 above the reactor inner container 416 for the p-type semiconductor layer film formation came larger than the preset value 150° C., and at this time point, the setting was gradually so changed that the output value 200 W of the RF power source 421 came to be 2,000 W, then the setting was gradually so changed that the output value 2,000 W of the RF power source 417 came to be 200 W (first discharge switching step).

Thereafter, the film formation was continued, and the value indicated by the thermocouple 432 above the reactor inner container 420 came larger than the preset value 150° C., at the point of time of which the setting was gradually so changed that the output value 200 W of the RF power source 417 came to be 2,000 W, and thereafter the setting was gradually so changed that the output value 2,000 W of the RF power source 421 came to be 200 W (second discharge switching step).

In the subsequent film formation as well, the above series of first and second discharge switching steps were repeated at the point of time when the value of temperature indicated by the thermocouple in the p-type semiconductor layer film formation reactor in which discharge was kept generated at 2,000 W came larger than the preset value 150° C., continuing the film formation. Thus, photovoltaic devices were fabricated in the same manner as in Example.

As a comparative example of Example 2 (Comparative Example 2), photovoltaic devices were fabricated in the same manner as in Example 2 except that the first and second discharge switching steps were not carried out in the p-type semiconductor layer film formation and the electric power applied from the RF power source 417 and the electric power applied from the RF power source 421 were set constant at 2,000 W and 200 W, respectively.

These photovoltaic devices were evaluated in the same manner as in Example 1. As the result, it was ascertained that in the photovoltaic devices fabricated in Comparative Example 2, the initial photoelectric conversion efficiency showed a tendency to decrease with the passage of film formation time, but, in the photovoltaic devices fabricated in Example 2, the initial photoelectric conversion efficiency was restored every time the discharge switching step was carried out in the p-type semiconductor layer film formation.

### Example 3

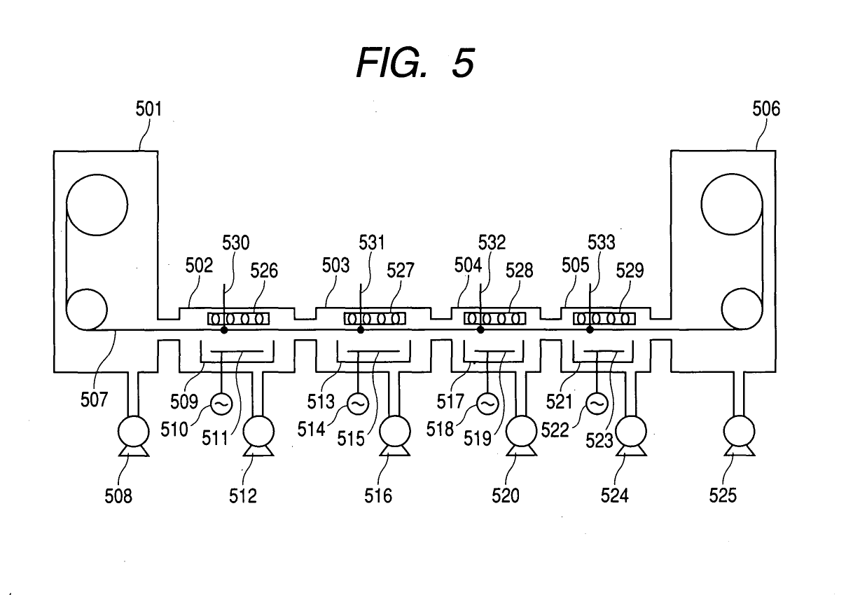

In this Example, photovoltaic devices were fabricated by a continuous process using a deposited-film formation system shown in FIG. 5. The system shown in FIG. 5 is basically constituted of a beltlike substrate 507, a delivery chamber 501, a wind-up chamber 506, an n-type semiconductor layer forming reactor 502, an i-type semiconductor layer forming reactor 503 and p-type semiconductor layer forming reactors 504 and 505 which are connected via gas gates. Reference numerals 508, 512, 516, 520, 524 and 525 denote vacuum pumps, and reference numerals 511, 515, 519 and 523 denote cathode electrodes which are connected to RF power sources 510, 514, 518 and 522, respectively.

In the respective reactors 502, 503, 504 and 505, reactor inner containers 509, 513, 517 and 521, respectively, are provided.

In the respective reactors, infrared lamp heaters 526, 527, 528 and 529 are also provided at spaces on the side opposite to the film formation space, interposing the beltlike substrate 507 between them. Each of thermocouples 530, 531, 532 and 533 for monitoring the temperature of the beltlike substrate 507 is so connected as to come into contact with the beltlike substrate 507, and the substrate is controlled to the desired temperature by means of a temperature control system (not shown).

First, in the delivery chamber 501 of this deposited-film formation system, having a substrate delivery mechanism, a bobbin was set which was wound up with a beltlike substrate 507 (300 mm wide×0.2 mm thick) made of SUS 430BA stainless steel, having been sufficiently degreased and cleaned and on which a thin silver film 100 nm thick and a thin ZnO film 1 μm thick were vacuum-deposited as the lower electrode by sputtering. Then the beltlike substrate 507 was allowed to pass through the n-type semiconductor layer forming reactor 502, the i-type semiconductor layer forming reactor 503, the p-type semiconductor layer forming reactors 504 and 505 and up to the wind-up chamber 506, having a substrate wind-up mechanism, and its tension was adjusted to an extent that it did not slacken.

Next, the insides of the delivery chamber 501, reactors 502, 503, 504 and 505 and wind-up chamber 506 were evacuated to a vacuum of 1×10⁻⁴ Pa or less by means of the vacuum pumps 508, 512, 516, 520, 524 and 525, respectively.

As heat treatment before the film formation, 500 sccm each of He gas was fed into the reactors 502, 503, 504 and 505 through gas feed pipes (not shown). The valve travel of throttle valves was so adjusted that the internal pressure of each of the delivery chamber 501, reactors 502, 503, 504 and 505 and wind-up chamber 506 came to be 130 Pa, where the insides of the respective chambers and reactors were evacuated by means of the vacuum pumps. Thereafter, the beltlike substrate 507 and inside materials of the reactors 502 to 505 were heated to 400° C. by means of the infrared lamp heaters 526, 527, 528 and 529 for heating. In this state, the system was left standing for 1 hour.

Next, in preparation for n-type semiconductor layer film formation, a temperature control device (not shown) was so set that the value of temperature indicated by the thermocouple 530 came to be 270° C., and the beltlike substrate 507 was heated with the infrared lamp heater 526. Through gas feed inlets (not shown), 100 sccm of SiH₄ gas, 500 sccm of PH₃/H₂ (1%) gas and 700 sccm of H₂ gas were fed into the reactor inner container 509. The valve travel of a conductance control valve was so adjusted that the pressure of the discharge chamber came to be 130 Pa, followed by evacuation by means of the vacuum pump 512. The discharge means was so set that the output value of the RF (13.56 MHz) power source 510 came to be 100 W, and the RF power was applied to the electrode 511 to generate discharge in the reactor inner container 509.

In preparation for i-type semiconductor layer film formation, a temperature control device (not shown) was so set that the value of temperature indicated by the thermocouple 531 came to be 300° C., and the beltlike substrate 507 was heated with the infrared lamp heater 527. Through the gas feed inlet (not shown), 800 sccm of SiH₄ gas, 900 sccm of GeH₄ gas and 3000 sccm of H₂ gas were fed into the reactor inner container 513. The valve travel of a conductance control valve was so adjusted that the pressure of the discharge chamber came to be 130 Pa, followed by evacuation by means of the vacuum pump 516. The discharge means was so set that the output value of the RF (13.56 MHz) power source 514 came to be 1,500 W, and the RF power was applied to the electrode 515 to generate discharge in the reactor inner container 513.

In preparation for p-type semiconductor layer film formation, temperature control devices (not shown) were so set that the values of temperature indicated by the thermocouples 532 and 533 came to be 150° C., and the beltlike substrate 507 was heated with the infrared lamp heaters 528 and 529. Through the gas feed inlets (not shown), 10 sccm of SiH₄ gas, 500 sccm of BF₃/H₂(1%) gas and 5,000 sccm of H₂ gas were fed into each of the reactor inner containers 517 and 521. The valve travel of a conductance control valve was so adjusted that the pressure of the discharge chamber came to be 130 Pa, followed by evacuation by means of the vacuum pumps 520 and 524. The discharge means was so set that the output value of the RF power source 518 came to be 2,000 W, and the RF power was applied to the electrode 519 to generate discharge in the reactor inner container 517. The reactor inner container 521 was kept in the state that discharge was not generated.

Subsequently after the preparation for the film formation of the respective layers, the beltlike substrate 507 was transported at a speed of 1,000 mm/min to start the formation of the n-type semiconductor layer, i-type semiconductor layer and p-type semiconductor layer on the beltlike substrate 507.

About 2.5 hours after the beginning of the film formation, the value indicated by the thermocouple 532 above the reactor inner container 517 for the p-type semiconductor layer film formation came larger than the preset value 150° C., and at this time point, the discharge means was so set that the output value of the RF power source 522 came to be 2,000 W, and the RF power was applied to the electrode 523 to generate discharge in the reactor inner container 521. After the discharge took place in the reactor inner container 521, the electric power from the RF power source 518 was stopped to extinguish the discharge in the reactor inner container 517 (first discharge switching step).

After this first discharge switching step, the thermocouple 532 indicated 150° C., and the film formation was continued in a temperature-controlled state, where the value indicated by the thermocouple 532 that had exceeded 150° C. returned to the state it was controlled at 150° C.

Thereafter, the film formation was continued, and the value indicated by the thermocouple 533 above the reactor inner container 521 came larger than the preset value 150° C., and at this time point, the discharge means was so set that the output value of the RF power source 518 came to be 2,000 W, and the RF power was applied to the electrode 519 to generate discharge in the reactor inner container 517. After this discharge took place, the electric power from the RF power source 522 was stopped to extinguish the discharge in the reactor inner container 521 (second discharge switching step).

In the subsequent film formation as well, the above series of first and second discharge switching steps were repeated at the point of time when the value of temperature indicated by the thermocouple in the p-type semiconductor layer film formation reactor in which discharge was kept generated came larger than the preset value 150° C., continuing the film formation.

After the beltlike substrate 507 was transported for one roll, all the discharge, all the gas feed, all the electrification of lamp heaters and the transport of the beltlike substrate 507 were stopped. Next, chamber purging N₂ gas was fed into chambers (feeding member not shown) to return the inside to the atmospheric pressure, and the beltlike substrate having the respective semiconductor layers formed thereon and wound up in the wind-up chamber 506 was taken out.

The beltlike substrate having the respective semiconductor layers formed thereon, thus taken out, was cut into unit cells. On the p-type semiconductor layer of each unit cell, ITO (In₂O₃+SnO₂) was deposited by vacuum deposition in a thickness of 100 nm as the transparent electrode, and further Al was deposited by vacuum deposition in a thickness of 1 μm as the collector electrode. Thus, photovoltaic devices were fabricated.

As a comparative example of Example 3 (Comparative Example 3), photovoltaic devices were fabricated in the same manner as in Example 3 except that the first and second discharge switching steps were not carried out in the p-type semiconductor layer film formation, the RF power source 518 and the electrode 519 were used from the beginning of film formation until the completion of film formation for one roll of the beltlike substrate 507 and the discharge was generated only in the reactor inner container 517 without being generated in the reactor inner container 521.

To make evaluation, samples of Example 3 and Comparative Example 3 were irradiated with the light of a sunlight spectrum of AM −1.5 at an intensity of 100 mW/cm², using a solar simulator, and a voltage-current curve was prepared to measure the initial photoelectric conversion efficiency of the photovoltaic devices.

As the result, the same results as those in example 1 and Comparative Example 1 were obtained. That is, it was ascertained that in the photovoltaic devices fabricated in Comparative Example 3, the initial photoelectric conversion efficiency showed a tendency to decrease with the passage of film formation time, but, in the photovoltaic devices fabricated in Example 3, the initial photoelectric conversion efficiency was restored every time the discharge switching step was carried out in the p-type semiconductor layer film formation.

### Example 4

In this Example, photovoltaic devices were fabricated in the same manner as in Example 3 except that the p-type semiconductor layer was formed under the following conditions for film formation.

In this Example, in preparation for p-type semiconductor layer film formation, the discharge means was so set that the output value of the RF power source 518 came to be 2,000 W, and the RF power was applied to the electrode 519 to generate discharge in the reactor inner container 517. At the same time, the discharge means was so set that the output value of the RF power source 522 came to be 200 W, and the RF power was applied to the electrode 523 to generate discharge in the reactor inner container 521. About 2.5 hours after the beginning of the film formation, the value indicated by the thermocouple 532 above the reactor inner container 517 for the p-type semiconductor layer film formation came larger than the preset value 150° C., and at this time point, the setting was gradually so changed that the output value 200 W of the RF power source 522 came to be 2,000 W, and thereafter the setting was gradually so changed that the output value 2,000 W of the RF power source 518 came to be 200 W (first discharge switching step).

Thereafter, the film formation was continued, and the value indicated by the thermocouple 533 above the reactor inner container 521 came larger than the preset value 150° C., and at this time point, the setting was gradually so changed that the output value 200 W of the RF power source 518 came to be 2,000 W, and the setting was gradually so changed that the output value 2,000 W of the RF power source 522 came to be 200 W (second discharge switching step).

In the subsequent film formation as well, the above series of first and second discharge switching steps were repeated at the point of time when the value of temperature indicated by the thermocouple in the p-type semiconductor layer film formation reactor in which discharge was kept generated at 2,000 W came larger than the preset value 150° C., continuing the film formation. Thus, photovoltaic devices were fabricated.

As a comparative example of Example 4 (Comparative Example 4), photovoltaic devices were fabricated in the same manner as in Example 4 except that the first and second discharge switching steps were not carried out in the p-type semiconductor layer film formation and the electric power applied from the RF power source 518 and the electric power applied from the RF power source 522 were set constant at 2,000 W and 200 W, respectively.

These photovoltaic devices were evaluated in the same manner as in Example 1. As the result, it was ascertained that in the photovoltaic devices fabricated in Comparative Example 4, the initial photoelectric conversion efficiency showed a tendency to decrease with the passage of film formation time, but, in the photovoltaic devices fabricated in Example 4, the initial photoelectric conversion efficiency was restored every time the discharge switching step was carried out in the p-type semiconductor layer film formation.

### Example 5

In this Example, photovoltaic devices were fabricated in the same manner as in Example 1 except that the p-type semiconductor layer was formed under the following conditions for film formation.

That is, in Example 1, the first switching step was carried out at the point of time when, about 2.5 hours after the beginning of the film formation, the value indicated by the thermocouple 431 above the reactor inner container 416 for the p-type semiconductor layer film formation came larger than the preset value 150° C., but in this Example the container for the discharge was switched from the reactor inner container 416 to the reactor inner container 420 at the point of time when not the temperature but the self-bias voltage of the electrode 418 came higher than 150 V (first discharge switching step).

After the discharge was switched, the film formation was continued, and the self-bias voltage of the electrode 422 came higher than 150 V, and at this time point, the container for the discharge was switched to the reactor inner container 416 (second discharge switching step).

The photovoltaic devices thus fabricated were evaluated in the same manner as in Example 1. As the result, the same results as those in Example 1 were obtained, and it was ascertained that the discharge switching step was effective.

### Example 6

In this Example, photovoltaic devices were fabricated in the same manner as in Examples 1 except that the p-type semiconductor layer was formed under the following conditions for film formation.

That is, in Example 1, the first switching step was carried out at the point of time when, about 2.5 hours after the beginning of the film formation, the value indicated by the thermocouple 431 above the reactor inner container 416 for the p-type semiconductor layer film formation came larger than the preset value 150° C., but in this Example the container for the discharge was switched from the reactor inner container 416 to the reactor inner container 420 at the point of time when not the temperature but the self-bias electric current of the electrode 418 came higher than 2 A (first discharge switching step).

After the discharge was switched, the film formation was continued, and the self-bias electric current of the electrode 422 came higher than 2 A, and at this time point, the container for the discharge was switched to the reactor inner container 416 (second discharge switching step).

The photovoltaic devices thus fabricated were evaluated in the same manner as in Example 1. As the result, the same results as those in Examples 1 were obtained, and it was ascertained that the discharge switching step was effective.

### Example 7

In this Example, the discharge switching step carried out in the p-type semiconductor layer film formation in Examples 1 was carried out in the i-type semiconductor layer film formation, using a system (not shown). More specifically, the step of switching the discharge electrode to another electrode when the value of substrate temperature in the i-type semiconductor layer film formation reactor, indicated by the thermocouple came larger than the preset value of the desired temperature, was carried out to fabricate photovoltaic devices. Evaluation was made in the same manner as in Example 1. As the result, the same results as those in Examples 1 were obtained, and it was ascertained that the discharge switching step was also effective in the i-type semiconductor layer film formation.

### Example 8

In this Example, the discharge switching step carried out in the i-type semiconductor layer film formation in Example 7 was carried out in the n-type semiconductor layer film formation, using a system (not shown) to fabricate photovoltaic devices. Evaluation was made in the same manner as in Example 1. As the result, the same results as those in Examples 1 were obtained, and it was ascertained that the discharge switching step was also effective in the n-type semiconductor layer film formation.

As described above, according to the present invention, the temperature rise caused by long-time film formation in the deposited-film formation system can be prevented and the temperature can be so controlled as to be optimum for substrate processing. Hence, the deposited-film formation process and formation system having high productivity can be provided which can prevent characteristics from deteriorating over time and can keep minimum the scattering of characteristics at the time of mass production, to stably fabricate photovoltaic devices having high photoelectric conversion efficiency.

What is claimed is:

1. A deposited-film formation process in which a source gas is fed into a discharge space of a reactor and an electric power is applied to generate discharge in the discharge space to decompose the source gas, thereby forming a deposited film; the process comprising disposing a plurality of discharge means in the reactor and having:
a first step of applying an electric power to a first discharge means to generate discharge to form the deposited film; and
a second step of applying an electric power to a second discharge means to generate discharge to form the deposited film;
said first step and said second step being switched from one to another at a stated timing.

2. A deposited-film formation process in which a source gas is fed into a discharge space of a reactor and an electric power is applied to generate discharge in the discharge space to decompose the source gas, thereby forming a deposited film; the process comprising disposing a plurality of discharge means in the reactor and having:
a first step of applying to a first discharge means an electric power larger than that for a second discharge means to generate discharge to form the deposited film; and
a second step of applying to the second discharge means an electric power larger than that for the first discharge means to generate discharge to form the deposited film;
said first step and said second step being switched from one to another at a stated timing.

3. A deposited-film formation process in which a source gas is fed into a discharge space of a reactor and an electric power is applied to generate discharge in the discharge space to decompose the source gas, thereby forming a deposited film; the process comprising disposing a plurality of reactors having at least one discharge means and having:
a first step of applying an electric power to a first discharge means in a first reactor to generate discharge to form the deposited film; and
a second step of applying an electric power to a second discharge means in a second reactor to generate discharge to form the deposited film;
said first step and said second step being switched from one to another at a stated timing.

4. A deposited-film formation process in which a source gas is fed into a discharge space of a reactor and an electric power is applied to generate discharge in the discharge space to decompose the source gas, thereby forming a deposited film; the process comprising disposing a plurality of reactors having at least one discharge means and having:
a first step of applying to a first discharge means in a first reactor an electric power larger than that for a second discharge means in a second reactor to generate discharge to form the deposited film; and
a second step of applying to the second discharge means in the second reactor an electric power larger than that for the first discharge means in the first reactor to generate discharge to form the deposited film;
said first step and said second step being switched from one to another at a stated timing.

5. The deposited-film formation process according to claim 2, wherein in the first step the electric power is applied to the second discharge means to generate discharge to an extent that does not affect the film formation, and in the second step the electric power is applied to the first discharge means to generate discharge to an extent that does not affect the film formation.

6. The deposited-film formation process according to claim 1, wherein the first step and the second step are switched from one to another on the basis of a film formation temperature that has reached a temperature within a temperature range set beforehand.

7. The deposited-film formation process according to claim 1, wherein said first step and said second step are switched from one to another on the basis of a self-bias voltage that has reached a voltage within a voltage range set beforehand.

8. The deposited-film formation process according to claim 1, wherein said first step and said second step are switched from one to another on the basis of a self-bias electric current that has reached an electric current within an electric-current range set beforehand.

9. The deposited-film formation process according to claim 1, wherein said first step and said second step are switched from one to another within a film formation time range set beforehand.

10. The deposited-film formation process according to claim 1, wherein said first and second discharge means are controlled within a stated temperature range.

11. The deposited-film formation process according to claim 1, which comprises a step of keeping the electric power applied to said first discharge means and said second discharge means to generate discharge through the respective discharge means when said first step and said second step are switched from one to another.

12. The deposited-film formation process according to claim 1, wherein, when said first step and said second step are switched from one to another, the electric power for said first discharge means is gradually decreased or increased and the electric power for said second discharge means is gradually increased or decreased.

13. The deposited-film formation process according to claim 1, wherein the deposited film formed through said first step and the deposited film formed through said second step are semiconductor layers having the same conductivity type.

14. The deposited-film formation process according to claim 1, wherein a distance between said first and second discharge means and a substrate on which the deposited films are formed is in the range of from 5 mm to 50 mm, and a pressure at which the deposited films are formed is in the range of from 10 Pa to 800 Pa.

15. A deposited-film formation system in which a source gas is fed into a discharge space of a reactor and an electric power is applied to generate discharge in the discharge space to decompose the source gas, thereby forming a deposited film; the system comprising:
a plurality of discharge means disposed in the reactor; and
a means for switching i) a first step of generating discharge by a first discharge means to form the deposited film and ii) a second step of generating discharge by a second discharge means to form the deposited film, from one to another on the basis of a value detected by a means for detecting a stated film formation parameter.

16. A deposited-film formation system in which a source gas is fed into a discharge space of a reactor and an electric power is applied to generate discharge in the discharge space to decompose the source gas and thereby form a deposited film; the system comprising:
a plurality of discharge means disposed in the reactor; and
a means for switching i) a first step of applying to a first discharge means an electric power larger than that for a second discharge means to generate discharge to form the deposited film and ii) a second step of applying to the second discharge means an electric power larger than that for the first discharge means to generate discharge to form the deposited film, from one to another on the basis of a value detected by a means for detecting a stated film formation parameter.

17. A deposited-film formation system in which a source gas is fed into a discharge space of a reactor and an electric power is applied to generate discharge in the discharge space to decompose the source gas, thereby forming a deposited film; the system comprising:
a plurality of discharge means disposed in the reactor; and
a means for switching i) a first step of applying an electric power to a first discharge means in a first reactor to generate discharge to form the deposited film and ii) a second step of applying an electric power to a second discharge means in a second reactor to generate discharge to form the deposited film, from one to another on the basis of a value detected by a means for detecting a stated film formation parameter.

18. A deposited-film formation system in which a source gas is fed into a discharge space of a reactor and an electric power is applied to generate discharge in the discharge space to decompose the source gas, thereby forming a deposited film; the system comprising:
a plurality of reactors having at least one discharge means, disposed in the reactor; and
a means for switching i) a first step of applying to a first discharge means in a first reactor an electric power larger than that for a second discharge means in a second reactor to generate discharge to form the deposited film and ii) a second step of applying to the second discharge means in the second reactor an electric power larger than that for the first discharge means in the first reactor to generate discharge to form the deposited film, from one to another on the basis of a value detected by a means for detecting a stated film formation parameter.

19. The deposited-film formation system according to claim 15, wherein said film formation parameter is film formation temperature.

20. The deposited-film formation system according to claim 15, wherein said film formation parameter is self-bias voltage.

21. The deposited-film formation system according to claim 15, wherein said film formation parameter is self-bias electric current.

22. The deposited-film formation system according to claim 15, wherein said film formation parameter is film formation time.

23. The deposited-film formation system according to claim 15, wherein said first and second discharge means are controlled within a stated temperature range.

24. The deposited-film-formation system according to claim 15, wherein, when said first step and said second step are switched from one to another, the electric power for said first discharge means is gradually decreased or increased and the electric power for said second discharge means is gradually increased or decreased.

25. The deposited-film formation system according to claim 15, wherein the deposited film formed through said first step and the deposited film formed through said second step are semiconductor layers having the same conductivity type.
